(19) United States
(12) Patent Application Publication
(10) Pub. No.: US 2021/0274689 A1
(43) Pub. Date: Sep. 2, 2021

(54) ARRANGEMENT COMPRISING A HOUSING AND A POWER ELECTRONICS CIRCUIT ARRANGED THEREIN ON A HOUSING BOTTOM

(71) Applicant: Vitesco Technologies GmbH, Hannover (DE)

(72) Inventors: Mircea BIRDEANU, Muenchen (DE); Sorin ANDREI, Muenchen (DE); Andrei-Radu NEGRILA, Muenchen (DE); Sebastian TAUBERT, Muenchen (DE); Eduard Iosif TRIF, Muenchen (DE)

(21) Appl. No.: 17/254,975

(22) PCT Filed: Jun. 19, 2019
(86) PCT No.: PCT/EP2019/066168

§ 371 Date: Dec. 22, 2020

(30) Foreign Application Priority Data
Jun. 22, 2018 (EP) 18465540

(51) Int. Cl. H05K 7/20; H05K 7/14

(52) U.S. Cl. CPC H05K 7/20918; H05K 7/20927; H05K 7/1427; H05K 7/20409

(57) ABSTRACT

An arrangement includes a housing and a power electronics circuit disposed on a housing base in the housing. A cavity with connections, which lead to the housing exterior, for supplying and discharging a cooling liquid, is formed at least in the housing base. Cooling fins are formed on that side of the housing base which faces away from the cavity. A fan which is driven by an electric motor is disposed in the housing in such a way that the air flow of the fan is cooled by the cooling fins and then draws heat from the power electronics circuit.

DE 10 2007 061 593 A1 discloses an arrangement comprising a housing and a power electronics circuit which is arranged on a housing base in said housing, in which arrangement a cold distributor on which cooling fins are formed and which has connections, which lead to the housing exterior, for supplying and discharging a cooling liquid is also arranged on this housing base. A fan is formed in the housing, which fan is preferably driven by the coolant flow and the air flow of which fan is cooled by the cooling fins and then draws heat from the power electronics circuit. Individual components of the power electronics circuit can be directly connected to the cold distributor via inflows and outflows in order to be directly cooled by the coolant in this way. However, this is very complicated.

The object of the invention is therefore to specify an arrangement comprising a housing and a power electronics circuit which is arranged on a housing base in said housing, which arrangement provides effective cooling of the power electronics circuit in a simpler and flexible manner.

The object is achieved by an arrangement as claimed in claim 1. Advantageous developments are specified in the dependent claims.

Accordingly, in an arrangement comprising a housing and a power electronics circuit which is arranged on a housing base in said housing, a cavity with connections, which lead to the housing exterior, for supplying and discharging a cooling liquid is formed at least in the housing base, wherein cooling fins are formed on that side of the housing base which is averted from the cavity, and wherein a fan which is driven by an electric motor is arranged in the housing in such a way that the air flow of said fan is cooled by the cooling fins and then draws heat from the power electronics circuit.

The power electronics circuit is therefore arranged on the housing base which functions as a cold distributor and therefore directly cools not only the cooling fins but rather also the components of the power electronics circuit which are arranged on said housing base. In addition, a fan ensures circulation of air through the cooling fins and to the power electronics circuit. In this case, the fan is driven by an electric motor and is therefore independent of a coolant flow.

In a first variant of the arrangement according to the invention, the electric motor is arranged in the housing. As a result, it is not necessary to guide the drive shaft through a housing wall.

In a second variant of the arrangement according to the invention, the electric motor is arranged outside the housing, as a result of which it is possible to replace the electric motor without having to open the housing.

Here, the electric motor can advantageously be arranged on a housing wall.

The invention will be explained in more detail below on the basis of exemplary embodiments with the aid of figures, in which:

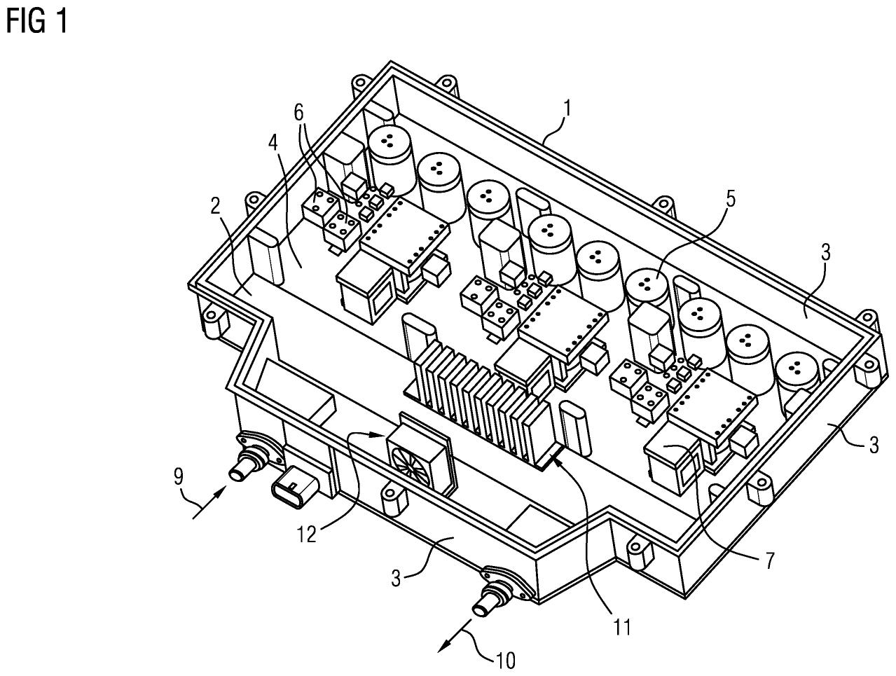

FIG. 1 shows a first variant of an arrangement according to the invention,

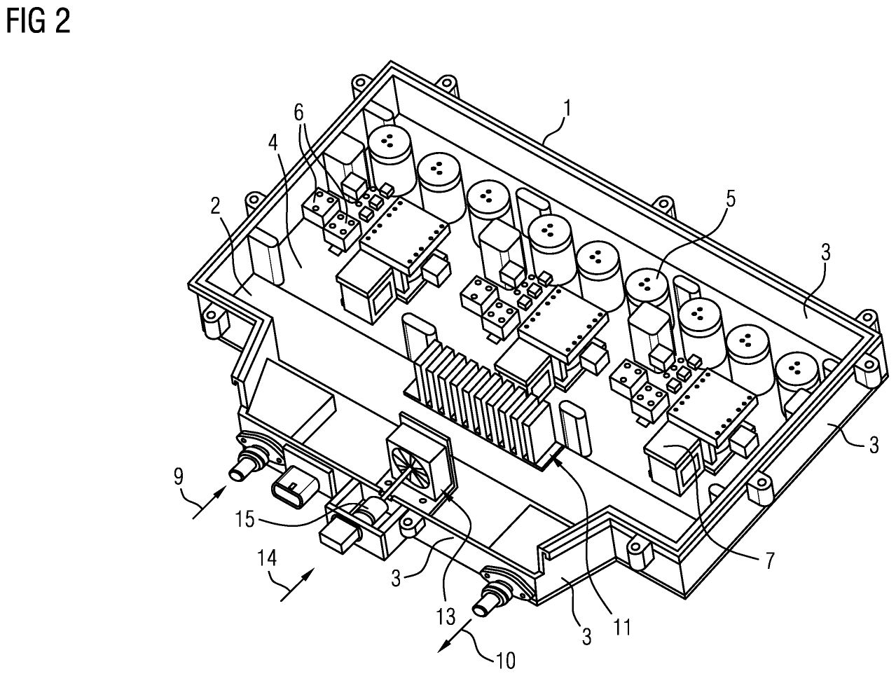

FIG. 2 shows a second variant of an arrangement according to the invention, and

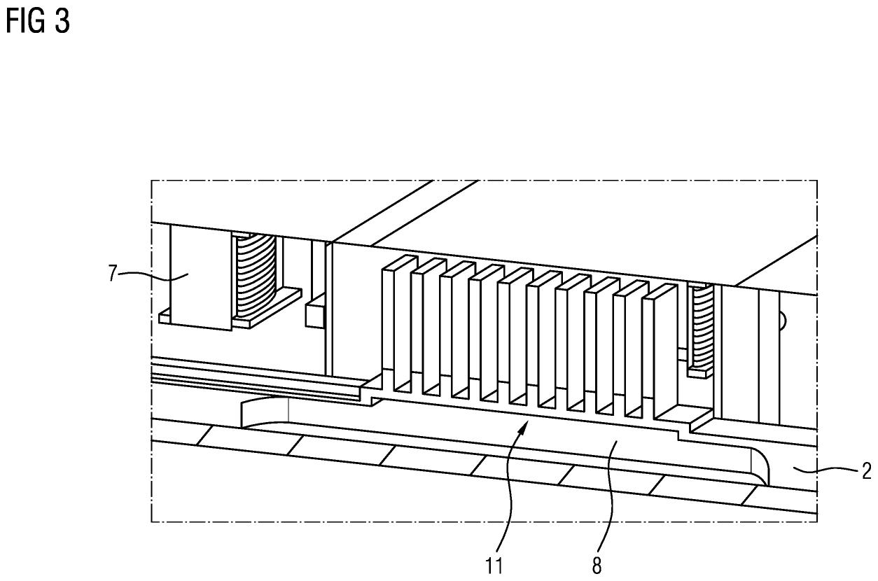

FIG. 3 shows a detail and cross section through an arrangement according to the invention which shows the cavity in the housing base.

The arrangement according to the exemplary embodiment of FIG. 1 has a housing 1 which is shown in the open state, that is to say without a cover, and has a housing base 2 and housing walls 3. Electrical and electronic components, such as capacitors 5, power semiconductor switching elements 6 and coils 7, are arranged on a printed circuit board 4. This power electronics circuit can be, for example, a charging circuit for conductive or inductive charging of energy stores, for example in a motor vehicle. The printed circuit board 4 is arranged on the housing base 2.

A cavity 8 which is connected to a coolant inlet 9, which leads to the housing exterior, and a coolant outlet 10 is formed in the housing base 2 according to FIG. 3. The housing base 2 and therefore the power electronics circuit which is arranged on it are cooled, or heat is drawn from them, in this way.

In addition, cooling fins 11 which are positioned upright on the housing base 2 and project into the housing 1 in the illustrated exemplary embodiment are arranged above the cavity 8. In this case, the cooling fins 11 can be arranged at various angles with respect to one another in order to influence an air flow which is generated by a fan 12 in its direction of flow.

In the exemplary embodiment of FIG. 1, the fan 12 is designed with an integrated electric motor, so that the electric motor is also arranged within the housing 1. This has the advantage that no coupling between the drive of the fan 12 and the fan 12 itself and also no passage in a housing wall 3 for a drive shaft are required.

During operation of the fan 12 with an integrated electric motor, air is guided past the cooling fins 11, which are cooled by the coolant flowing in the cavity 8, and is blown to the components 5, 6, 7 of the power electronics circuit in a manner possibly guided by the position of the cooling fins 11, so that they are advantageously cooled or heat is drawn from them.

The exemplary embodiment, illustrated in FIG. 2, of an arrangement according to the invention comprising a housing and a power electronics circuit which is arranged on a housing base in said housing is of substantially identical design to the variant of FIG. 1, so that identical parts are provided with the same reference symbols and will not be described again.

In contrast to the first variant however, here the electric motor 14 which drives the fan 13 is arranged outside the housing 1 on a housing wall 3 and is connected to the fan 13 by means of a coupling 15 and a drive shaft which is guided through the housing wall 3.

This second variant has the advantage that the housing 1 does not have to be opened when replacing the electric motor 14.

FIG. 3 shows, in an enlarged detail illustration, the cooling fins 11 which in this case are formed in one piece with that part of the housing base 2 which delimits the cavity 8 with respect to the interior of the housing.

1-4. (canceled)

5. An arrangement, comprising:
a housing having a housing base and defining a housing exterior;
a power electronics circuit disposed in said housing on said housing base;
a cavity formed at least in said housing base and defining a side of said housing base facing away from said cavity, said cavity having connections leading to said housing exterior for supplying and discharging a cooling liquid;
cooling fins formed on said side of said housing base facing away from said cavity; and
a fan driven by an electric motor, said fan being disposed in said housing and providing an air flow being cooled by said cooling fins and drawing heat from said power electronics circuit.

6. The arrangement according to claim 5, wherein said electric motor is disposed in said housing.

7. The arrangement according to claim 5, wherein said electric motor is disposed outside said housing.

8. The arrangement according to claim 7, wherein said housing has a housing wall, and said electric motor is disposed on said housing wall.
